(19) United States
(12) Patent Application Publication
(10) Pub. No.: US 2021/0305024 A1
(43) Pub. Date: Sep. 30, 2021

(54) PLASMA CLEANING FOR PACKAGING ELECTRONIC DEVICES

(71) Applicant: Texas Instruments Incorporated, Dallas, TX (US)

(72) Inventors: Enis Tuncer, Dallas, TX (US); John Paul Tellkamp, Rockwall, TX (US)

(21) Appl. No.: 16/828,869

(22) Filed: Mar. 24, 2020

(51) Int. Cl. H01J 37/32; H01L 21/02

(52) U.S. Cl. CPC H01J 37/32651; H01J 2237/335; H01J 37/32715; H01L 21/02057

(57) ABSTRACT

In a described example, a method includes loading at least one package substrate strip including electronic device dies mounted on the at least one package substrate strip into a plasma process chamber; positioning at least one E-field shield in the plasma process chamber spaced from and over the at least one package substrate strip; and plasma cleaning the at least one package substrate strip.

### TECHNICAL FIELD

This disclosure relates generally to packaged electronic devices, and more particularly to plasma cleaning of package substrate strips with mounted electronic devices during the packaging process.

### SUMMARY

In a described example, a method includes loading at least one package substrate strip including electronic device dies mounted on the at least one package substrate strip into a plasma process chamber; positioning at least one E-field shield in the plasma process chamber spaced from and over the at least one package substrate strip; and plasma cleaning the at least one package substrate strip.

### BRIEF DESCRIPTION OF THE DRAWINGS

FIG. 1 is a block diagram of a plasma cleaning tool.

FIG. 2 is block diagram of a plasma cleaning tool of an arrangement with E-field shields.

FIG. 3 is an expanded view of a portion of a tray for use in the arrangements with support rails and with an E-field shield.

FIG. 4A-4E are example E-field shield designs for use in the arrangements.

FIGS. 5A-5I illustrate in a series of cross sections the major steps in manufacturing a packaged electronic device with plasma cleaning and reduced or no delamination between mold compound and the surfaces of the electronic device and the package substrate frame.

FIG. 6 is a projection view of a packaged electronic device.

FIG. 7 is a flow diagram with descriptions of the manufacturing steps illustrated in FIGS. 5A-5I.

### DETAILED DESCRIPTION

Corresponding numerals and symbols in the different figures generally refer to corresponding parts, unless otherwise indicated. The figures are not necessarily drawn to scale.

In this description, certain structures and surfaces are described as “perpendicular” to one another. For purposes of this disclosure, two elements are “perpendicular” when the elements are intended to form a 90-degree angle at their intersection. However, the term “perpendicular” as used herein also includes surfaces that may slightly deviate from 90 degrees due to manufacturing tolerances. Generally, for purposes of this description, an expected manufacturing tolerance is =/−10% for any measured characteristic. For example, for purposes of this description, an angle intended to be a perpendicular angle that falls between 80 degrees and 100 degrees when measured is perpendicular.

As is further described hereinbelow, certain structures and surfaces are described as being “horizontal” or “vertical.” A horizontal surface has an orientation in a single plane such as a tabletop or the floor of a room. A vertical surface has an orientation in a single plane that is perpendicular to a horizontal surface. For example, a vertical wall of a room is perpendicular to the horizontal floor. However, when surfaces intended to be horizontal or vertical are manufactured, some variation occurs due to manufacturing defects or tolerances. A surface that is intended to be vertical is a vertical surface, as described herein. A surface that is intended to be a horizontal surface is a horizontal surface, as described herein. Further, the surfaces may be described as being in a single plane, this does not mean the surfaces are perfectly planar. In manufacturing, the surfaces may vary and the surfaces may be rough or smooth, and may have warp or other slight variations in planarity. The relative positions of these surfaces when an object including these surfaces is rotated or otherwise placed in a different position than that described does not change the meanings of the terms horizontal or vertical as used herein.

The terms “encapsulated” and “encapsulates” are used herein to describe a packaged electronic device covered in a mold compound. However, the term “encapsulated” means that while the electronic device and portions of the package substrate frame such as a lead frame are covered in mold compound, some portions of the lead frame may be exposed to form external leads or external terminals of the packaged electronic device. A term commonly used for encapsulation in integrated circuit (IC) packaging is “potting.” Another term used is “encapsulation.” During an electronic device potting process, a lead frame with a device bonded to it is placed in an injection or transfer mold. Mold compound such as filled epoxy resin is injected in the mold to cover, encapsulate, or “pot” the device plus lead frame and form a packaged electronic device.

The terms “plasma ashing” and “plasma cleaning” are used herein. In some uses of the term plasma ashing, a layer such as a photoresist is removed from a surface by placing the workpiece, such as a semiconductor die or wafer, in a process chamber. In a vacuum, a single species gas is introduced and a plasma is formed using ionizing energy. The energized ions or atoms are attracted to impact the surface of the workpiece with sufficient energy to sputter the photoresist layer. The material is then removed from the process chamber by vacuum. When photoresist is removed in this process a white residue is removed, so the plasma process is often called “ashing.” In this description the surfaces are being cleaned of oxides and metal and solder residue in a plasma process, and so the process cleans the surfaces, and the process is described herein as “plasma cleaning” or as “plasma ashing.”

The term “E-field shield” is used herein. As used herein, an E-field shield is a conductive element placed between a source of an electric field and a device to be protected. The E-field shield receives at least a portion of the electric field, reducing or preventing the electric field from reaching the protected device. In the arrangements, a plasma cleaning process is used where atoms are accelerated in an electric field and directed towards a target to be cleaned. The atoms impact the target and remove residues by sputtering on impact. Sharp conductive edges and other non-uniform portions of the target can cause the electric field to concentrate in certain areas, forming a non-uniform electric field, which causes a non-uniform sputtering process. Use of an E-field shield in the arrangements can control and make the electric field at the target more uniform, reducing or preventing dilatory effects including over-sputtering and non-uniform sputtering at the target.

The term “packaged electronic device” is used herein. A “packaged electronic device” is an electronic device in a protective package. The package includes a package substrate for mounting one or more electronic devices, such as semiconductor devices, passive devices such as capacitors, resistors, inductors, coils and transformers, sensor devices, couplers such as opto-couplers, or micro-electromechanical systems (“MEMS”) devices. A semiconductor device can be a digital or analog transistor, a sensor, a digital or analog integrated circuit, a micro electro-mechanical system (MEMS) device, a high power transistor, a high power circuit such as a switching power supply. The term “electronic device die” is used herein. An electronic device die is an individual die taken from a semiconductor substrate where the devices are manufactured using semiconductor manufacturing processes.

The packaged electronic device further includes terminals or leads located at an exterior surface to provide electrical connection to the devices mounted within the package, the terminals also provide mechanical mounting points for the packaged electronic device. In example arrangements, the terminals can be leads extending from the body of the package electronic device. In alternative arrangements, the terminals can be “no-lead” terminals, terminals that are coextensive with the package body.

The term “package substrate” is used herein. A package substrate is a component used in mounting and packaging a semiconductor die. Examples shown in the figures herein show a metal lead frame as the package substrate. Other package substrates useful with the arrangements include pre-molded lead frames (PMLF). In addition, useful package substrates for the arrangements include conductive lead frames, partially etched or half-etched conductive lead frames, and molded interconnect substrates (MIS). The package substrate can be a film, laminate or tape that carries conductors, or can be a printed circuit board such as reinforced fiber glass (such as FR4), bismaleimide triazine (BT) resin, alumina, silicon carbide, or aluminum nitride. The materials for the package substrate can include conductors such as copper and copper alloys, iron-nickel alloys such as Alloy 42, and gold and gold alloys. Gold, silver, palladium, nickel and tin platings can be made on the metal conductors. These platings improve solderability, bondability, reduce diffusion and reduce possible corrosion. The package substrates can include dielectrics including silicon, glass, mold compound, ceramic, polyimide, fiberglass, and resins. Multiple levels of conductors spaced from one another by dielectric layers and conductive vias forming conductive connections between the multiple conductor levels can be used in the package substrates.

In examples, a packaged electronic device is formed in a leaded package. An example is a small outline integrated circuit (SOIC) package. The package substrate is a lead frame with portions of the lead frame leads forming leads extending from the body of the finished package, these leads are then shaped to form terminals for the packaged semiconductor device. In an alternative a “no-lead” or “leadless” package is used. In a quad flat no-lead (QFN) package, the lead frame leads end coextensively with the molded package body to form terminals on four sides of the package body that are “no lead” terminals for surface mounting the device to a system board. Other no-lead packages can be used.

Packaging electronic devices involves mounting electronic device dies on a package substrate strip such as a lead frame strip (a lead frame strip includes multiple individual lead frames connected together by saw streets). Devices can be coupled electrically to conductors in the package substrate by bond wires in a wire bonding process. Ribbon bonds can be used instead of bond wires. In an alternative arrangement, the semiconductor dies can be coupled to the package substrate in a flip chip process, using solder reflow of solder on conductive posts that extend from bond pads on the electronic devices. The package substrate is then subjected to encapsulating (potting) of the electronic device, covering a portion of the package substrate strip with a mold compound such as a filled epoxy resin. Thermoset mold compound can be used. Room temperature liquid mold compound can be used. After molding to cover the device, the mold compound can be cured using cooling time, or using time with applied thermal or UV energy, depending on the particular mold compound used. Individual packaged electronic devices are then formed by cutting through the mold compound and saw streets.

The process of mounting the electronic device die on the package substrate typically involves forming wire bonds between bond pads on the electronic device dies and conductive leads of the lead frame. In an alternative arrangement, flip chip packaging is used where the die is mounted to the package substrate using solder connections. Solder resin may be applied to the package substrate to facilitate solder wetting. In a thermal reflow process, the package substrate strip with mounted electronic device dies is heated to flow the solder. Solder joints form between the electronic device dies and the package substrate strip.

Residues such as metals, solder, solder resin and including surface oxides formed on the package substrate strip and electronic device dies during heating in the presence of air cause poor adhesion between the mold compound and the surface of electronic device dies and the surfaces of the package substrates. Poor mold compound adhesion can result in delamination of the mold compound from the surfaces of the package substrate and the electronic device dies during reliability testing, such as temperature and humidity cycling. Resulting failures result in increased scrap and reduced yield. Plasma cleaning in an oxygen or oxygen/argon plasma after the electronic device die mount, and prior to the encapsulation, cleans surfaces by removing residues such as plating residues, solder residue, and solder resin residue, oxides, and other organic residues such as fingerprints. Plasma cleaning also removes surface oxides that cause poor mold compound adhesion.

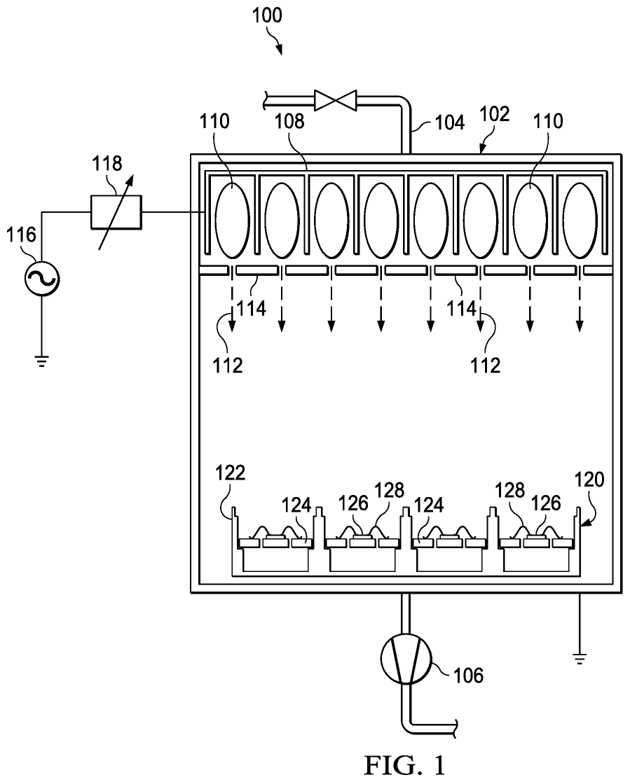

FIG. 1 is a block diagram of a plasma tool 100 such as a plasma ashing tool. Plasma cleaning or plasma ashing is used to remove organic and oxide residues from the surface of mounted electronic device dies and package substrates. The mounted electronic device dies 126 and package substrate strips 124 are loaded onto a tray 120 in the process chamber 102 of the plasma tool 100. The tray 120 contains multiple support rails 122 so that multiple package substrate strips 124 can be loaded into the tray 120 and processed simultaneously. Plasma processing gases such as oxygen and argon from gas supply 104 are introduced into the chamber 102 through a port opposite the tray 120 (on the “ceiling” or top surface of process chamber 102, the upper surface as oriented in FIG. 1) and are removed from the process chamber 102 through the “floor” (the bottom surface of process chamber 102 as oriented in FIG. 1) by a vacuum pump 106. In this plasma tool 100 configuration, a hollow cathode discharge (HCD) array 108 ionizes the reaction gases forming plasmas 110 near the ceiling of the chamber 102. A radio frequency (RF) generator 116 that is coupled to the chamber 102 through a matching network 118 powers the HCD array 108. Reactive ions 112, such as ionized oxygen molecules, ionized oxygen atoms, and ionized argon (Ar) atoms generated in the plasma 110, enter the process chamber 102 through a showerhead 114 below the HDC array 108. The reactive atoms 112 react with and remove organic residues forming carbon dioxide and water vapor. Energetic argon atoms break up and remove (sputter) surface oxides. The trays such as 120 are typically stainless steel, although other metals such as nickel and nickel alloys can also be used.

Electric fields between the showerhead 114 and the tray 120 accelerate the argon atoms 112, providing the atoms with sufficient energy to impact the package substrate strips and remove surface oxides and other residues that otherwise would prevent strong adhesive bonding between the mold compound and the surfaces of the package substrate strips 124 and mounted dies 126. Package substrate strips 124 such as lead frames have a large variety of designs with a large range of metal densities, and with numerous metal edges and metal points. Electric fields in the plasma concentrate at metal edges and especially at metal points, forming high electric field regions. Charged argon atoms 112 can gain sufficient energy when accelerated in these concentrated electric fields to sputter metal from exposed surfaces such as lead frame (package substrate 124) metal and bond wire 128 metal. Sputtering can reduce the size of the bond wires 128, resulting in reliability failures. Sputtering can also redeposit metal on surfaces of the electronic device die 126 between bond wires 128, causing leakage paths to form. Leakage paths are especially problematic for high voltage electronic devices and can result in shorting and premature package failure in field use or during time dependent dielectric breakdown (TDDB) reliability testing.

In the arrangements, the problems of bond wire thinning and undesirable package substrate sputtering, as well as the problems of metal residue redeposited in unwanted areas of an electronic device during a plasma cleaning process, are addressed by disposing an E-field shield over a package substrate strip in the process chamber of a plasma cleaning tool. Use of the E-field shield results in increased uniformity of the E-field and increased control of the cleaning process, reducing or eliminating metal sputtering, preventing redeposition of metal sputter residue and reducing wire bond thinning during the cleaning process.

In the arrangements, an E-field shield can be designed for a particular lead frame or family of lead frames to make the E-field above the lead frame more uniform. The E-field shield can be removed from the plasma process chamber and can be replaced with another E-field shield when the package substrate being processed changes. In this way the E-field shield can be used to control the E-field above the package substrate, for example a lead frame for a particular product. A robot handler or other transfer mechanism that is used to move workpieces in and out of the process chamber in the plasma tool can remove and replace the E-field shields.

In an example application, a lead frame having two die mount areas that are electrically isolated is used to mount two semiconductor dies, the two semiconductor dies having bond pads that are coupled to leads on the lead frame using bond wires. At least one of the two semiconductor dies is a high voltage device. When high voltages are used in a wire bonded package, if the bond wires are thinned due to plasma sputtering, the packaged device can fail or have hot spots or have higher than expected resistance. Damage to bond wires and the leads of the lead frame can increase failures or reduce product lifetime. Use of the E-field shield in the arrangements enables forming a uniform E-field in the plasma tool that effectively cleans the package substrate and the dies, while also avoiding unwanted sputtering of the lead frame and avoiding damage to the bond wires.

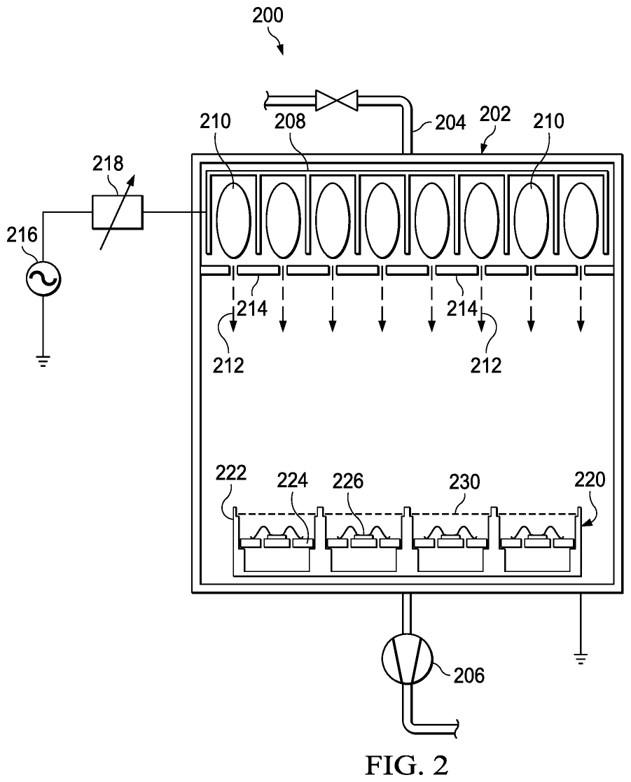

FIG. 2 illustrates a plasma tool 200 in an example arrangement. In FIG. 2, the plasma tool has increased uniformity of the electric field across the tray 220 and across the package substrate strips 224 (when compared to another tool such as 100 in FIG. 1). In FIG. 2 similar reference labels are used for similar elements as are shown in FIG. 1, for clarity. For example, tray 220 in FIG. 2 corresponds to tray 120 in FIG. 1. In this plasma tool 200, support rails 222 in tray 220 are designed to support at least one or more E-field shields 230 above package substrate strips 224 with mounted electronic device dies 226. The E-field shields 230 are made of metal, and are designed without sharp corners, and provide a uniform ground plane for the plasma. In an example the metal is stainless steel. In alternatives, metals such as gold, nickel, copper, palladium, and combinations or alloys of these can be used for the E-field shields. Plated metal used for lead frames can also be used to form E-field shields. Use of the E-field shields results in uniform acceleration of Ar ions 212 and uniform Ar ion sputtering energy across the tray 220. With the E-field shield, the sputter energy can be adjusted to be sufficient to remove surface oxides and other residues, but still keeping the sputter energy insufficient to undesirably sputter metal from the package substrate strip 224 and bond wires 228. Use of the arrangements improves device yield by reducing packaged electronic device failures due to shorts caused by sputtered metal leakage paths and by reducing or eliminating packaged unit failures due to sputter thinning of wire bonds and damage to package substrates.

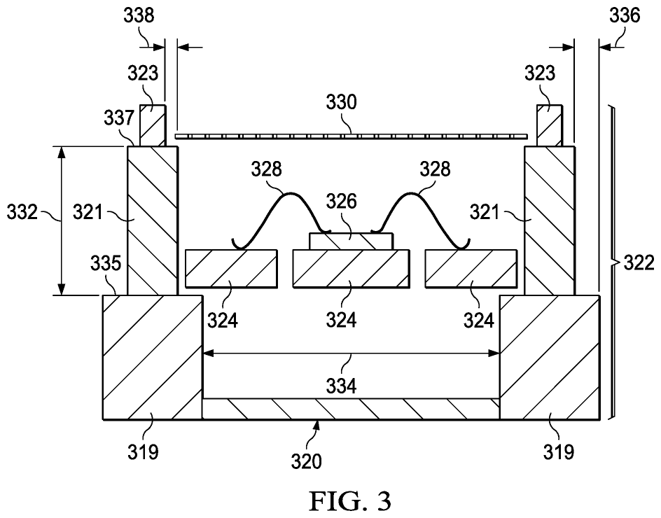

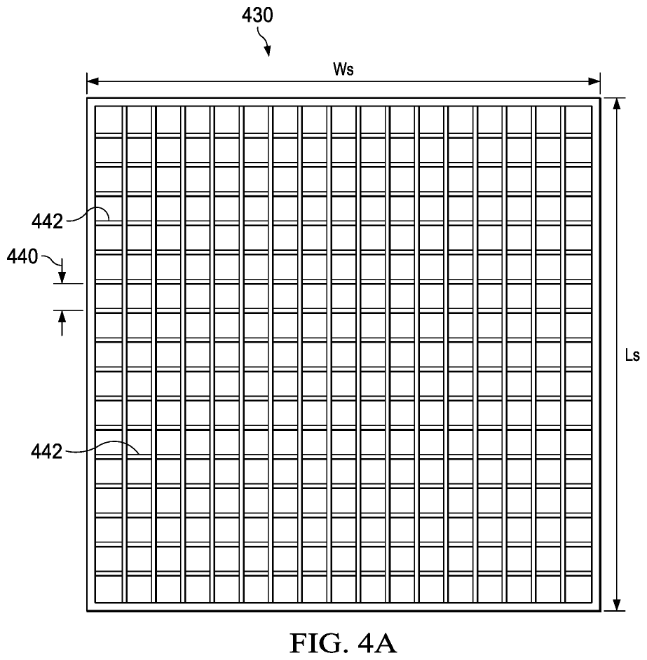

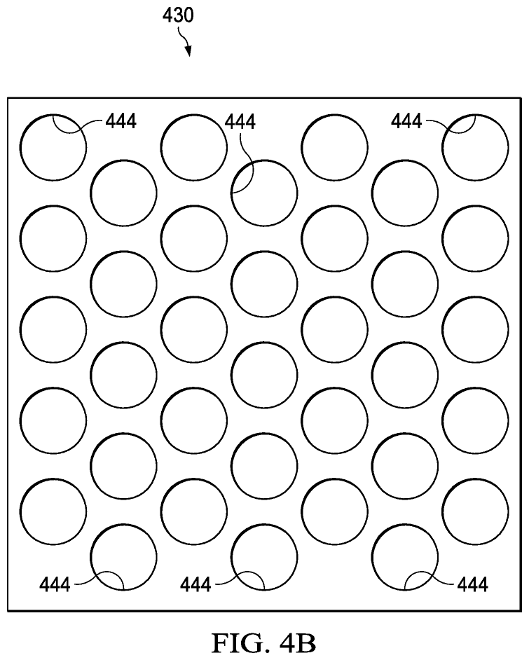

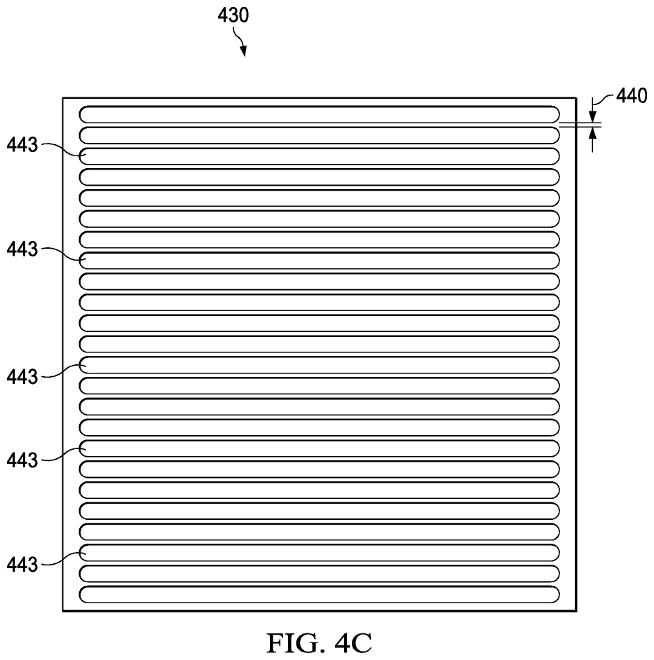

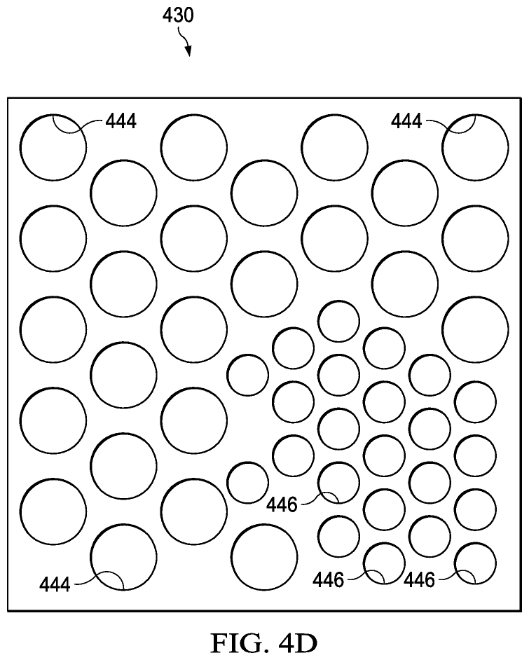

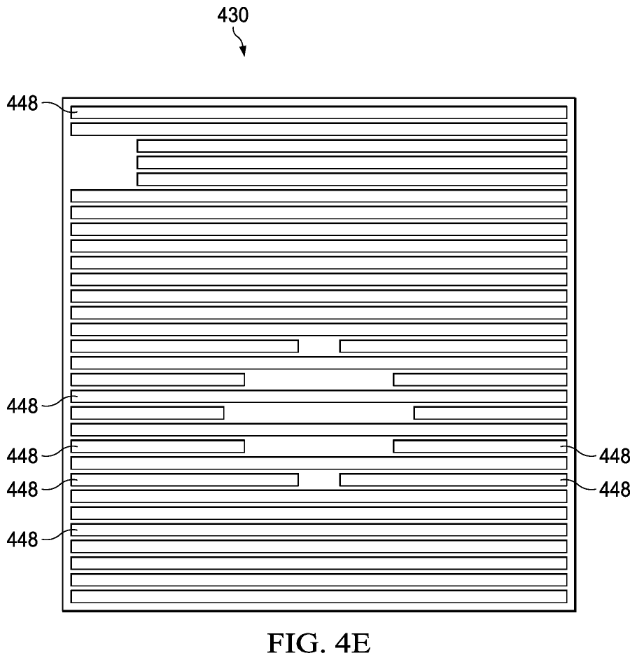

FIG. 3 is an expanded view of a portion of a tray 320 with support rails 322 for use in the arrangements. In FIG. 3 similar reference labels are used for similar elements as are shown in FIG. 2, for clarity. For example, tray 320 in FIG. 3 corresponds to tray 220 in FIG. 2. The support rails 322 are designed to accommodate at least one E-field shield 330. A package substrate strip 324 with mounted electronic device dies 326 is loaded onto the support rails 322. The mounted electronic device dies 326 are electrically connected to the package substrate strip 324 with wire bonds 328. Other means of connection such as ball bonds can be used. Support rails 322 in the tray 320 are designed so at least one E-field shield 330 can be loaded into the process chamber positioned between the plasma source (see FIG. 2) and the package substrate strip 324. In example arrangements, the E-field shield 330 is positioned between about 0.5 mm and 1 cm above the package substrate strip 324 so as not to touch any part of the package substrate strip 324, the electronic device dies 326, or the wire bonds 328. The E-field shield must be spaced from the closest portion of a lead frame, some lead frames have upper and lower portions such as downset lead frames, so the closest portion of the lead frame should be spaced at least 500 microns from the E-field shield. The E-field shield 330 can be a wire mesh or can be a metal plate with openings to allow the energized molecules and atoms (see 212, FIG. 2 and FIGS. 4A-4E)) to reach and clean the surfaces of the package substrate strip 324 and electronic device die 326. In the example of FIG. 3, the E-field shield 330 can be positioned using the support rails, while in alternative arrangements the E-field shield 330 can be supported using suspension, legs or by other support types. The E-field shield is positioned, in some manner, to be between the plasma and the package substrate strips, and to control the E-field above the package substrate strips/

The horizontal spacing 334 of the support rails 322 in the tray 320 is determined by the width of the package substrate strips 324 to be cleaned. Package substrate strip 324 width is typically between about 50 mm and 90 mm, although other package substrate strip 324 widths are also possible. In this example arrangement, the support rails 322 have three sections each with a different width: a base section 319 with a first width, an intermediate section 321 extending from the base section with a second width that narrower than the first width, and an end section 323 extending from the intermediate section with a third width that is narrower than the second width. The support rails 322 are vertical with the base 319 section proximate to the floor of the tray 320. First supports 335 with a width 336 between approximately 2 mm and 4 mm are formed between the base 319 and the intermediate section 321. The package substrate strips 324 are supported on these first support shelves 335 during plasma cleaning.

Second supports 337 with a width 338 between approximately 2 and 4 mm are formed between the intermediate section 321 and the upper end section 323. The at least one E-field shield 330 is supported on the second horizontal shelves 337 during plasma cleaning.

The second support 337 is spaced a distance 332 of greater than about 0.5 mm above the first support 335 to prevent the E-field shield 330 (lying on the second support 337) from contacting any portion of the underlying electrical device (lying on the first support 335.) The support rails 322 position the E-field shield 330 between the package substrate strips 324 and the plasma source (208, FIG. 2) during plasma cleaning. The E-field shield 330 provides uniform acceleration of plasma ions across the tray 320 and prevents metal from being sputtered from exposed metal on the electronic device dies 326 and on the package substrate strips 324.

A few representative examples of E-field shields 430 useful in the arrangements are illustrated in FIGS. 4A-4E. In FIGS. 4A-4E similar reference labels are used for similar elements as are shown in FIG. 3, for clarity. For example, E-field shield 430 in FIGS. 4A-4E correspond to E-field shield 330 in FIG. 3. The length Ls of the E-shield 430 is approximately the length of the package substrate strip (324, FIG. 3) being plasma cleaned. The width Ws of the E-shield 430 is approximately 4 to 8 mm wider than the width of the package substrate strip. The size of the openings in the E-field shield are relative to the openings in a package substrate, such as a lead frame. The openings in the E-field shield need to be about 50% smaller than the openings in the lead frame, +/−10%. The openings in the E-field shield can be aligned to the solid surfaces of the particular package substrate being cleaned, such as a lead frame. The E-field shield openings can be modified using experimental data and/or computer simulation such as Finite Element Analysis software. Openings in the E-field shield can be aligned with the solid portions of the lead frame, for example see FIGS. 4C and 4D, element 448 in FIG. 4D is arranged to be aligned above a lead frame opening.

The E-field shield 430 illustrated in the example of FIG. 4A is a uniform mesh. The gauge of the wires 442 that form the mesh and the spacing 440 of the wires can be selected as needed to prevent metal from being sputtered. Different package substrate strips with different metal densities and different numbers of metal corners may require different E-field 430 designs.

The example E-field shield 430 illustrated in FIG. 4B is a metal plate with circular holes that allow energized molecules and atoms from the plasma to reach and clean the surfaces of the package substrate strip and of the mounted electronic device. The size and spacing of the holes can be adjusted as needed to modify the E-field above the package substrate strip (such as 324, see FIG. 3) to prevent metal from being sputtered. Examination of a particular lead frame and designing an E-field shield can be done by placing openings in the E-field shield to correspond with regions on the lead frame to be cleaned, similar to mask design for a plasma sputtering operation. Experimentation with a target package substrate can be used to observe the E-field obtained, and the E-field shield can be modified.

The example E-field shield 430 illustrated in FIG. 4C is a metal plate with slits 443 in it that allow energized molecules and atoms from the plasma to reach and clean the surfaces of the package substrate strip and the mounted electronic device dies. The size and spacing 440 of the slits can be modified as needed to modify the E-field above the package substrate strip 324, FIG. 3 to prevent metal from being sputtered.

In FIGS. 4A, 4B, and 4C, the openings are uniform in size and are arranged uniformly across the E-field shield 430. As is illustrated in FIGS. 4D, and 4E, the openings need not be the same size and the spacing and density of the openings across the E-field shields 430 need not be uniform. The size, shape, spacing, and density of the openings can be adjusted as needed to accommodate individual package substrate strips.

The plasma cleaning tool (see 200 in FIG. 2) is arranged to accommodate at least one, or more, E-field shields. E-field shields enable uniform plasma cleaning of package substrate strips with mounted electronic device dies while avoiding metal sputtering that can cause reliability failures and yield loss.

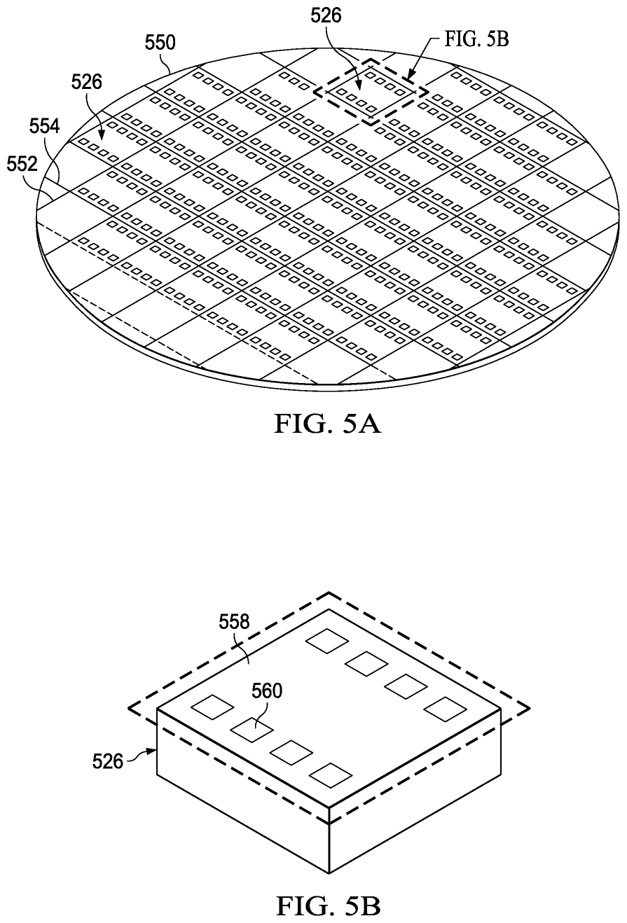

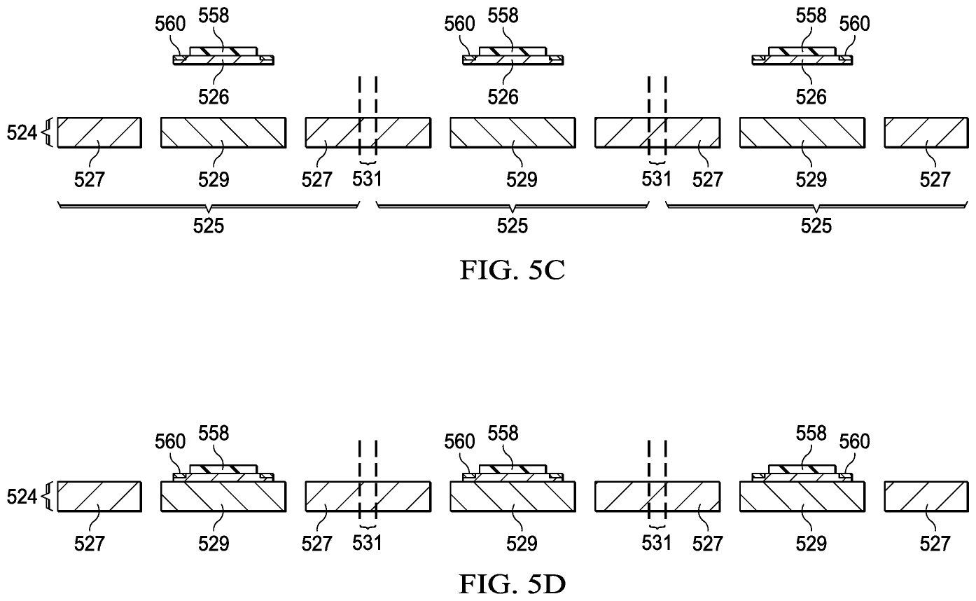

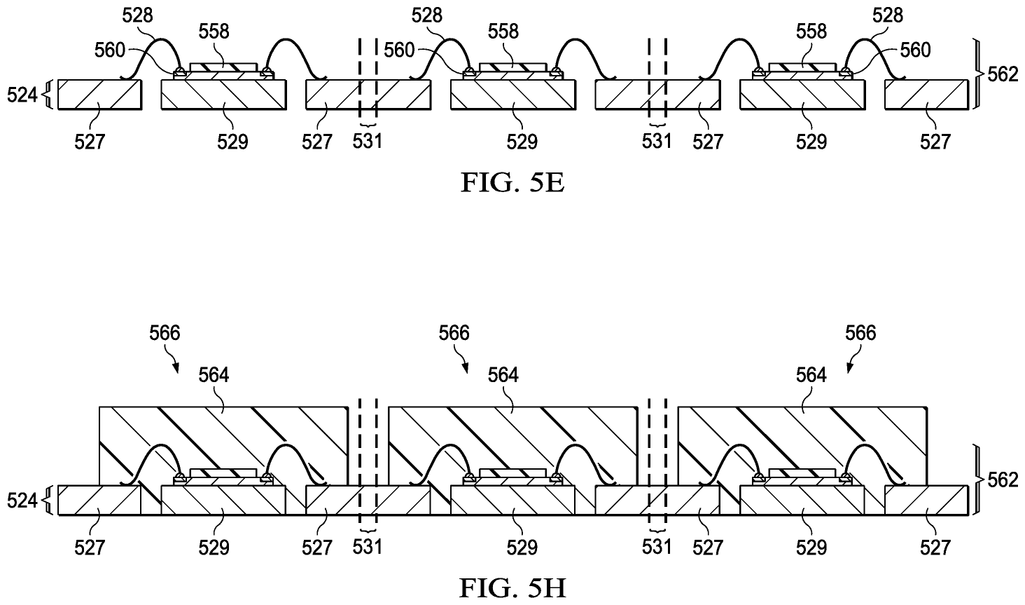

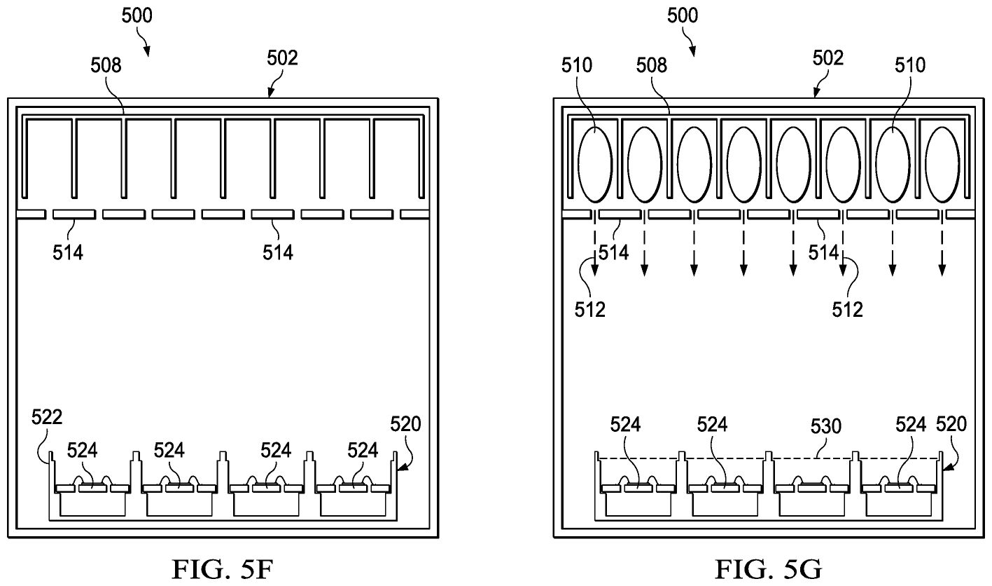

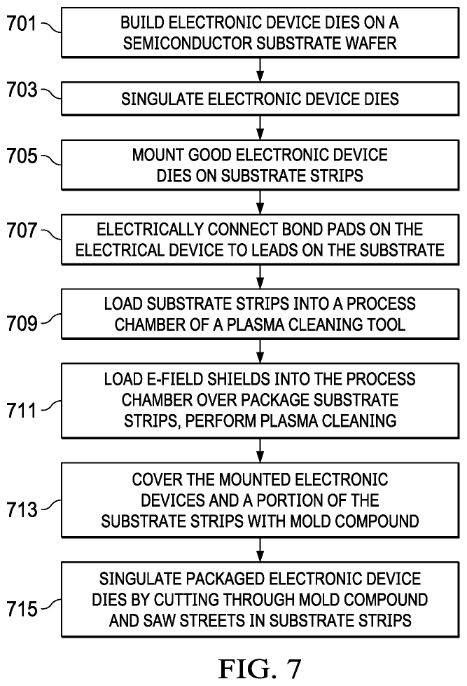

FIGS. 5A-5I describe the major steps in manufacturing a packaged device die that has robust adhesion between mold compound and the electronic device die and the package substrate strip. In FIGS. 5A-5I similar reference labels are used for similar elements as are shown in FIG. 3, for clarity. For example, package substrate strip 524 in FIGS. 5A-5I corresponds to package substrate strip 324 in FIG. 3. The major steps in FIGS. 5A-5I are described in flow diagram steps 701-713 in FIG. 7.

Electronic device dies 526 are built (step 701, FIG. 7) on semiconductor wafer 550 in FIG. 5A.

FIG. 5B (step 703) shows an electronic device die 526 that is singulated by cutting through the semiconductor wafer 550 along the horizontal (as the wafer 550 is oriented in FIG. 5B) 552 and vertical 554 scribe lanes. The electronic device dies 526 are coated with a dielectric protective overcoat 558 such as silicon dioxide, silicon nitride, silicon oxynitride, or polyimide. Openings in the protective overcoat 558 expose bond pads 560.

A cross sectional view of a package substrate strip 524 (such as a lead frame strip) is shown in FIG. 5C. The package substrate strip 524 is comprised of individual package substrate frames 525 (such as lead frames) connected together by saw streets 531. Electronic device dies 526 are positioned over die mount pads 529 in the package substrate frames 525 in the package substrate strip 524.

In FIG. 5D (step 705) the electronic device dies 526 are mounted on the die mount pads 529 of the package substrate strip 524.

In FIG. 5E (step 707) the electronic devices dies 526 are electrically connected to leads 527 on the package substrate frame 525. In this example, bond pads 560 on the electronic device dies 526 are electrically connected to the leads 527 with wire bonds 528. Other electrical connections such as ball bonds can also be used.

In FIG. 5F (step 709) multiple package substrate strips 524 with mounted device dies 526 are loaded into a process chamber 502. In this example, the package substrate strips 524 are loaded onto support rails 522 in the tray 520.

In FIG. 5G (step 711) E-field shields 530 are loaded onto the support rails 522. The E-field shields 530 are in close proximity to but are spaced at least 1 mm above the package substrate strips 524. Energized molecules and atoms 512, are formed in the plasma source 510 and are accelerated toward the package substrate strip 524 by electric fields between the showerhead 514 and the tray 520. These energized molecules and atoms 512 pass through the openings in the E-field shield 530 removing organic residues and surface oxides from the package substrate strips 524 and the electronic device dies 526. The E-field shields 530 prevent regions of concentrated electric fields from forming. Regions of concentrated electric fields can excessively accelerate ions causing sputtering of metal and other damage to the electronic device dies 526 and package substrate strips 524. The damage can result in reliability failures and yield loss. While a particular tray and support rails are described for the example of FIG. 5G, the E-field shields can be disposed in the process chamber above the package substrate strips in alternative ways. Suspension supports could be used. The E-field shield needs to be spaced from the package substrate and be between the plasma and the package substrate to control the E-field during the sputtering process on the package substrate.

The package substrate strips 524 are removed from the plasma process chamber 502 prior to covering the mounted electronic device 526 and a portion of the package substrate strips 524 with mold compound 564. See FIG. 5H (step 713). The mold compound 564 can be a polymeric material such as a filled epoxy resin or filled polyester resin. The plasma cleaning ensures strong adhesive bonding between the mold compound and surfaces of the electronic device dies 526 and the surfaces of the package substrate strip 524. The E-field shield 530 ensures metal from the package substrate is not sputtered and redeposited on the electronic device dies 526. Redeposited sputtered metal can cause leakage paths between the bond wires 528 resulting in failure of the packaged electronic devices 566. The use of the E-field shield also allows for a uniform E-field, so that corner effects and other non-uniform process conditions can be reduced or eliminated.

Individual packaged electronic device dies (FIG. 5I) with good adhesion (no delamination) between the mold compound 564 and the surface of the package substrate leads 527 and 529 and the surface of the electronic device die 526 are singulated (step 715) by cutting through the mold compound 564 and through the saw streets 531 between the individual package substrate frames 525.

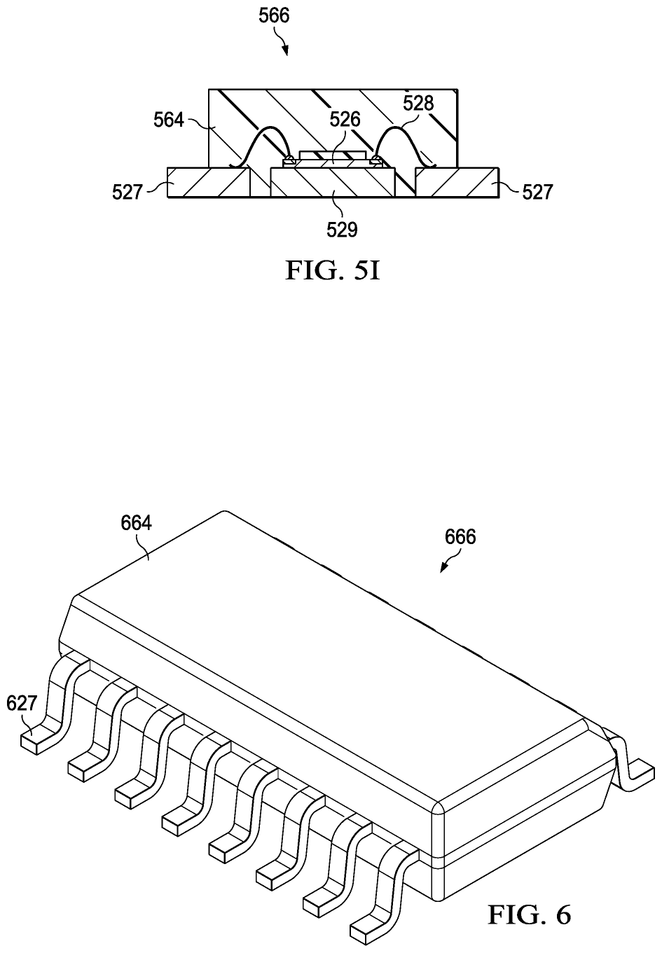

FIG. 6 is a projection view of a packaged electronic device 666. A portion of the package substrate leads 627 remains uncovered by the mold compound 664. The leads 627 are shaped in a trim form tool to enable mounting the packaged electronic device 666 onto leads of a package substrate such as a printed circuit board (not shown). Various package types including packages using lead frames and other package substrates can be plasma cleaned prior to molding using the arrangements. Wire bonded and flip chip mounted dies can be cleaned in the arrangements.

Modifications are possible in the described arrangements, and other alternative arrangements are possible within the scope of the claims.

What is claimed is:

1. An apparatus, comprising:
a plasma process chamber with a bottom surface and a top surface;
a tray in the plasma process chamber configured to support at least one package substrate strip above the bottom surface; and
at least one E-field shield in the plasma process chamber positioned above the tray.

2. The apparatus of claim 1, the tray further comprising support rails wherein the support rails and the tray comprise stainless steel.

3. The apparatus of claim 2, wherein the support rails further comprise a first support at a first position above the bottom surface; and a second support configured to support the at least one E-field shield at a position above the first support.

4. The apparatus of claim 3, wherein a spacing between the second support and the first support is at least 1 mm.

5. The apparatus of claim 4, wherein the first support has a first width in a range of 2 to 4 mm.

6. The apparatus of claim 5, wherein the second support has a second width is in a range of 2 to 4 mm.

7. The apparatus of claim 6, wherein the first width and the second width are the same.

8. The apparatus of claim 1, wherein the E-field shield has openings that are about 50% smaller than corresponding openings in a package substrate strip to be cleaned.

9. The apparatus of claim 1, wherein openings in the E-field shield are circular.

10. The apparatus of claim 1, wherein openings in the E-field shield are rectangular with rounded corners.

11. A method, comprising:
loading at least one package substrate strip including electronic device dies mounted on the at least one package substrate strip into a plasma process chamber;
positioning at least one E-field shield in the plasma process chamber spaced from and over the at least one package substrate strip; and
plasma cleaning the at least one package substrate strip.

12. The method of claim 11 and further comprising:
removing the cleaned at least one package substrate strip from the plasma process chamber;
covering the electronic device dies and a portion of the at least one package substrate strip with mold compound; and
forming individual packaged electronic devices by cutting through the mold compound and cutting through the at least one package substrate strip along saw streets.

13. The method of claim 11, wherein the plasma process chamber further comprises a tray configured to support the package substrate strip including support rails that have at least three portions: a base portion with a first width; an intermediate portion extending from the base portion with a second width that is narrower than first width, and an end portion extending from the intermediate portion with a third width that is narrower than the second width.

14. The method of claim 13, wherein a width of the intermediate portion is at least 1 mm.

15. The method of claim 13, wherein the at least one package substrate strip is loaded onto a first support formed between the base portion and the intermediate portion.

16. The method of claim 15, wherein a width of the first support is between 2 and 4 mm.

17. The method of claim 13, wherein the at least one E-field shield is loaded onto a second support formed between the intermediate portion and the end portion.

18. The method of claim 17, wherein a width of the second support is between 2 and 4 mm.

19. The method of claim 11, wherein the at least one E-field shield is positioned at a distance between 1 mm and 1 cm above the at least one package substrate strip.

20. The method of claim 11, wherein openings in the at least one E-field shield are circular.

21. The method of claim 11, wherein the openings in the at least one E-field shield are rectangular with rounded corners.

22. The method of claim 11, wherein the E-field shield comprises stainless steel.

23. The method of claim 11 wherein the at least one E-field shield is of a metal taken from a group consisting essentially of stainless steel, nickel, and nickel alloy.

24. A plasma cleaning tool, comprising:
a process chamber having a top surface and a bottom surface;
a tray configured to support a package substrate strip spaced from the bottom surface; and
a removable E-field shield positioned in the process chamber above the tray.

25. The plasma cleaning tool of claim 24, wherein f the E-field shield comprises openings that are 50% smaller than corresponding openings in a package substrate strip.

26. The plasma cleaning tool of claim 25, wherein the openings in the E-field shield are circular.

27. The plasma cleaning tool of claim 25, wherein the openings in the E-field shield are rectangular with rounded corners.

28. A method for packaging electronic devices, comprising:
loading at least one package substrate strip including electronic device dies mounted on the at least one package substrate strip into a plasma process chamber;
positioning at least one E-field shield in the process chamber spaced from and over the at least one package substrate strip;
plasma cleaning the at least one package substrate strip;
removing the at least one cleaned package substrate strip from the process chamber;
covering the electronic device dies and a portion of the at least one package substrate strip with mold compound; and
forming individual packaged electronic devices by cutting through the mold compound and cutting through the at least one package substrate strip along saw streets.
